(19) United States
(12) Patent Application Publication
(10) Pub. No.: US 2017/0069724 A1
(43) Pub. Date: Mar. 9, 2017

(54) IRIDIUM SILICIDE STRUCTURES AND METHODS

(71) Applicant: University of North Dakota, Grand Forks, ND (US)

(72) Inventors: Nuri Oncel, Grand Forks, ND (US); Rasika Nishantha Mohottige, Grand Forks, ND (US)

(21) Appl. No.: 15/254,060

(22) Filed: Sep. 1, 2016

Related U.S. Application Data
(60) Provisional application No. 62/214,008, filed on Sep. 3, 2015.

(51) Int. Cl. H01L 29/24; H01L 29/06; H01L 31/032; H01L 29/78; H01L 31/0352; H01L 21/02; H01L 21/477; H01L 31/18; H01L 29/04; H01L 31/036

(52) U.S. Cl. CPC H01L 29/24; H01L 29/045; H01L 29/0673; H01L 31/032; H01L 31/036; H01L 31/035227; H01L 21/02381; H01L 21/02433; H01L 21/02521; H01L 21/02603; H01L 21/477; H01L 31/1864; H01L 29/785

(57) ABSTRACT

An iridium silicide structure, devices made from iridium silicide structures, and associated methods are shown. Example devices include iridium silicide structures formed on a (110) surface of a silicon substrate. After formation of the iridium silicide structures, any number of possible electronic devices may be formed, including, but not limited to IR detectors and FinFET devices.

### CLAIM OF PRIORITY

This patent application claims the benefit of priority, under 35 U.S.C. §119(e), to U.S. Provisional Patent Application Ser. No. 62/214,008, entitled “IRIDIUM SILICIDE STRUCTURE AND METHODS,” filed on Sep. 3, 2015, which is hereby incorporated by reference herein in its entirety.

### STATEMENT REGARDING FEDERALLY SPONSORED RESEARCH

This invention was made with government support under NSF Grant No. DMR-1306101. The government has certain rights in the invention.

### TECHNICAL FIELD

Embodiments described herein generally relate to iridium silicide structures. Specific examples may include electronic devices that use iridium silicide nanowires as components.

### BACKGROUND

Iridium-silicides have the lowest (highest) Schottky barrier for holes (electrons) which can be used in various device applications. For example, among silicides, platinum-silicide/p-doped silicon diodes are employed in large focal plane arrays for detection in the medium-wavelength infrared light (3-5 μm). The Schottky barrier height between platinum-silicide and p-doped Si(001) is about 0.23 eV corresponding to a cutoff wavelength of 5.4 μm. In order to extend the cutoff wavelength, interfaces with lower Schottky barrier height can be used. The Schottky barrier height between iridium-silicide and p-doped silicon is approximately 0.17 eV corresponding to a cutoff wavelength of 7 μm. This makes iridium-silicide a promising material for a number of potential electronic devices.

### BRIEF DESCRIPTION OF THE DRAWINGS

FIG. 1 is a pair of Scanning Tunneling Microscope (STM) images of a silicon surface in accordance with some embodiments of the invention.

FIG. 2 shows STM images and a line scan profile of iridium silicide structures on a silicon surface in accordance with some embodiments of the invention.

FIG. 3 is an illustration of surface microstructure in accordance with some embodiments of the invention.

FIG. 4 is a Local Density of States (LDOS) graph of silicon surfaces and iridium silicide structures in accordance with some embodiments of the invention.

FIG. 5 is a block diagram of an example device using iridium silicide structures in accordance with some embodiments of the invention.

FIG. 6 is another block diagram of an example device using iridium silicide structures in accordance with some embodiments of the invention.

FIG. 7 is a flow diagram of a method of forming an iridium silicide structure in accordance with some embodiments of the invention.

FIG. 8 is an XPS plot of an iridium silicide structure in accordance with some embodiments of the invention.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

Physical and electronic properties of unidimensional iridium silicide nanowires are shown, as grown on Si(110) surface. In one example, the nanowires grow along [001] direction with an average length of about 100 nm. In one example, the nanowires have a band gap of about 0.5 eV and their electronic properties show similar features with the iridium silicide ring clusters formed on Ir modified Si(111) surface.

Ir (Iridium)-silicides have the lowest (highest) Schottky barrier for holes (electrons) which can be used in various device applications. For example, among silicides, Pt (Platinum)-silicide/p-doped Silicon (Si) diodes are employed in large focal plane arrays for detection in the medium-wavelength infrared light (3-5 μm). The Schottky barrier height between Pt-silicide and p-doped Si(001) is about 0.23 eV corresponding to a cutoff wavelength of 5.4 μm. In order to extend the cutoff wavelength, it is desirable to choose interfaces with lower Schottky barrier height. The Schottky barrier height between Ir-silicide/p-doped silicon is approximately 0.17 eV corresponding to a cutoff wavelength of 7 μm. Therefore, Ir-silicide is a promising material for devices such as infrared detector applications.

As continuous miniaturization challenges lithography based techniques, self-assembly based processes seem more attractive. One particular self-assembled component is self-assembled metal-silicide nanowires. These nanowires can function as low-resistance interconnects, as fins in FinFETs and as nanoelectrodes for attaching small electronic components within an integrated circuit.

A variety of metals are capable of forming self-assembled silicide nanowires on the surface of flat and/or vicinal Si substrates, however, chemical interactions and surface conditions specific to each metal and substrate dictate that formation of silicide nanowires must be evaluated on a case by case basis. Nanowires can be made up of various elements ranging from Bi and rare-earth metals to transition metals. In comparison to Si(111) and Si(001) surfaces, Si(110) surface has received less attention mainly because the surface reconstruction is complicated and it is difficult to grow large single domains. However, higher hole mobility in devices fabricated on Si(110) surface and the possibility of employing self-assembled nanowires in various applications have recently increased number of studies on these systems. Unlike 4-fold symmetric Si(001) surface, Si(110) surface is two-fold symmetric which can lead to formation of parallel nanowires. The present disclosure shows formation of Ir-silicide nanowires.

The Si(110) samples used in the Scanning Tunneling Microscopy/Spectroscopy (STM/STS) experiments were cut from nominally flat 76.2 mm by 0.38 mm, single side-polished n-type (phosphorous doped, R=1.0-10.0 Ohm-cm) wafers. The samples were mounted on molybdenum holders and contact of the samples to any other metal during preparation and experiment was carefully avoided. The STM/STS studies have been performed by using an ultra-high vacuum system (UHV) with a base pressure of 2×10−10 mbar equipped with an Omicron Variable Temperature STM. Before introducing Si(110) samples into the UHV chamber, samples were washed with isopropanol and dried under the flow of nitrogen gas. Si(110) samples were degassed extensively and after that flash-annealed at 1250° C. Then the sample was annealed at various temperatures to obtain various reconstructions of pristine Si(110) and Ir-silicide nanowires. (see details below) The sample temperature was measured with a pyrometer. The quality of the clean Si(110) samples was confirmed with STM prior to Ir deposition. Ir was deposited over the clean Si(110) surface from a current heated Ir wire (99.9%). All the STM experiments were performed at room temperature. I-V curves measured while measuring high resolution STM images of the surface. Then the measured I-V curves were averaged. The local density of states curves (LDOS) were calculated out of the I-V curves.

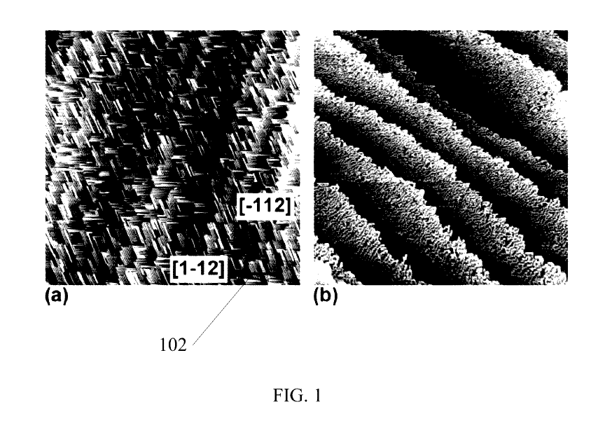

FIG. 1: a and b shows STM images of clean Si(110) annealed at 600° C. and 800° C., respectively. The arrows 102 indicate the high symmetry directions of the “16×2” domains. The sample bias and the tunneling current for the STM image in a (b) are −1.2 V (−1 V) and 0.2 nA (0.2 nA).

FIGS. 1a and 1b show two STM images of pristine Si(110) surface before Ir deposition. It has been shown that the reconstruction of Si(110) surface depends strongly on the annealing temperature. Annealing at 600° C. leads to the formation of well-defined “16×2” domains however annealing at and above 800° C. leads to the formation of the disordered phase. (see FIGS. 1a and 1b) So far different structures have been proposed to explain Si(110)-“16×2” phase. The adatom-tetramer-interstitial (ATI) is the most accepted of them. In this model, four adatoms and one first layer atom come together and form a pentagon that surrounds an interstitial atom at its center.

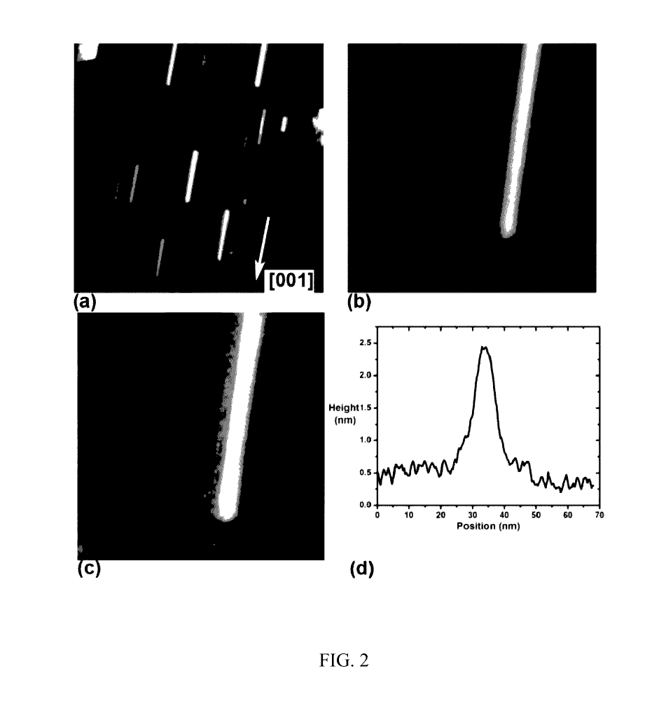

FIG. 2: (a) is a 400 nm×400 nm and (b) is a 100 nm×100 nm STM images of Ir modified Si(110) surface. Ir silicide nanowires grow along [001] direction.

In one example, after depositing iridium on the silicon surface, the sample is annealed at a temperature between 600° C. and 800° C. to form iridium silicide nanowires. In one example, after depositing 0.25 ML of Ir on the surface, the sample was annealed at 800° C. for two minutes while keeping the pressure below 2×10−10 mbar. FIG. 2a shows a large scale STM image of the surface where multiple nanowires are visible. The nanowires grow along the [001] direction. FIG. 2d shows a line scan graph measured on the nanowire shown in FIG. 2b. The average height, length and width of nanowires are 1.76 nm±0.32 nm, 106.27 nm±21.76 nm and 14.63 nm±2.97 nm respectively. The variances in length and width are correlated since the values closely follow the equation:

$${σ}_{A}^{2} = {〈 W 〉}^{2} {σ}_{L}^{2} + {〈 L 〉}^{2} {σ}_{W}^{2} + 2 〈 W \cdot L 〉 {σ}_{LW}$$

where σ_{A},σ_{L},σ_{W} are standard deviations of the area, the length and the width of the nanowires. [symbol] W [symbol] , [symbol] L [symbol] stand for expectation value of width and length of the nanowires. σ_{LW} represent covariance of width and length. The strong correlation between width and length of a nanowire indicates that the length and width must be physically coupled via strain, diffusion and etc.

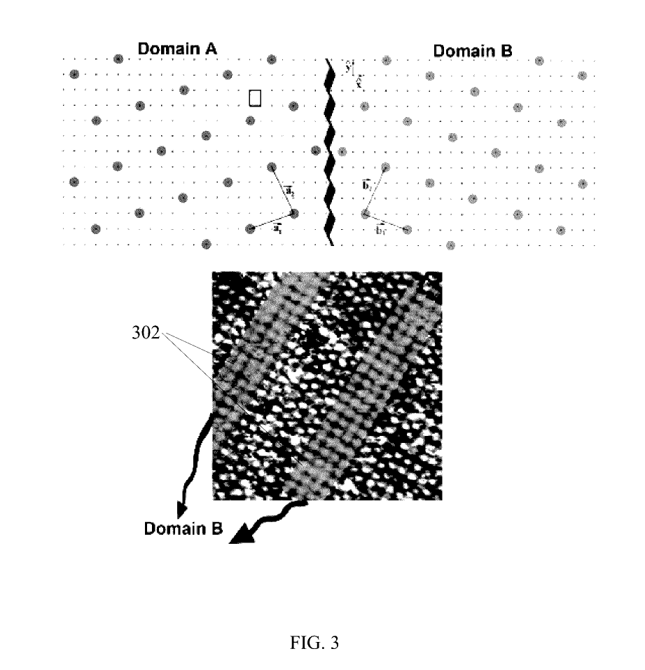

High resolution STM images similar to FIG. 2b show that the terraces on which nanowires form have a superstructure that looks rather different than the pristine Si(110) surface. The superstructure has two equivalent domains that are rotated with respect to each other. (See FIG. 3) Empty state image of the same region does not show any clear periodic structure. (FIG. 2c) With the help of the matrix notation, the unit cell of the superstructure can be defined as (for domain A, see FIG. 3):

$${M}_{terrace} = ( \begin{matrix}- 4 & - 1 \\ - 2 & 3\end{matrix} )$$

A careful analysis of STM images revealed that there are domain walls even within a single domain of the superstructure. (see FIG. 3) These walls separate well-defined periodic regions, marked by the green rectangles 302. The domain walls are even thicker than the domains themselves indicating that the corrugation of the superstructure/substrate potential is significantly small compared to the lateral interactions between the constituents of this superstructure. FIG. 3: Top: A schematic diagram of domain A (left) and domain B (right) of the superstructure is presented. Bottom: An STM image of the terrace showing the two B-type domains (green rectangles 302) separated by a domain wall.

FIG. 4 shows (a) LDOS graph measured on pristine Si(110)-“16×2” surface. (b) LDOS graphs measured on Ir-silicide nanowires (black) and terrace surrounding the nanowires (red). (c) dI/dV graph measured on Ir-silicide nanowires that shows a gap of about 0.5 eV.

Data for the electronic structure of Si(110)-“16×2” surface using angle resolved photoemission spectroscopy (ARPES) is available. ARPES data show that there are four surface states located at −0.2 eV, −0.4 eV, −0.75 eV and −1.0 eV. Using STS measurements, the state at −0.2 eV has been assigned to the pentagons and the rest of the states are attributed to the surface states at the step edges.

FIG. 4a shows the LDOS curve we measured. The presented LDOS curve reproduced most of the states below the Fermi level. One important difference is that the LDOS curve in FIG. 4a has a just single peak located at −0.3 eV instead of two peaks at −0.2 eV and −0.4 eV as measured before with ARPES. This can be due to the broadening of the STS peaks. The broadening corresponds to approximately 0.1 eV at room temperature. Published LDOS data also shows a single peak albeit that peak is located at 0.2 eV. On the other hand, the LDOS graph has a shoulder at 0.3 eV and two well resolved peaks at 0.75 eV and 1.3 eV which are also attributed to pentagons on the surface.

FIG. 4b shows two LDOS curves measured on Ir-silicide nanowires (black) and the terrace (red) surrounding them. The nanowires and the terrace have band gap of about 0.5 V (see FIG. 4c) which is significantly wider than the band gap of “16×2” domains (˜0.2 eV). Both LDOS curves have one well-resolved peak below the Fermi level. The peak coincides well with a well-known projected bulk band. However, it can still have some surface contribution.

Previously, we studied Ir ring clusters on Si(111) surface extensively. Ab-initio density functional theory calculations performed on this surface revealed that below the Fermi level, there is a state associated with Ir atoms embedded in the ring clusters. The position of this state in the spectrum almost perfectly matches with the peaks observed on the Ir-silicide nanowires and the underlying terrace. Above the Fermi level, the LDOS curves look different. The terrace has a broader feature originating from conduction band. On the other hand, the nanowires have two well-resolved states located at 0.75 eV and 1.4 eV. The position of the peaks are comparable to the position of peaks measured on Ir ring clusters. On Ir ring clusters, we determined that these peaks belong to Ir atom and six Si adatoms that constitute the rings. Similarities on the electronic properties between the two surfaces suggest that the building blocks of these nanowires may resemble Ir-ring clusters.

In summary, we report the formation of unidirectional Ir-silicide nanowires on Si(110) surface. The average length of nanowires is about 100 nm. Statistical analysis of the size distribution reveal that the length and width of the nanowires are correlated. The dimensions of these nanowires can be adjusted by changing growth parameters for the specific application. Ir-silicide nanowires are semiconductor with a band gap of about 0.5 eV. The position of the electronic states show similarities with the Ir-ring cluster of Ir modified Si(111) surface. The similarities of the electronic properties between Ir-silicide nanowires and Ir-ring clusters suggest that the chemical composition of both surfaces may be similar.

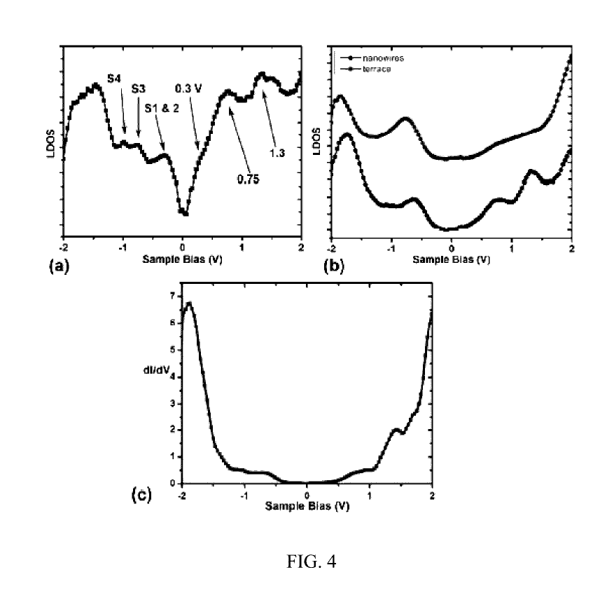

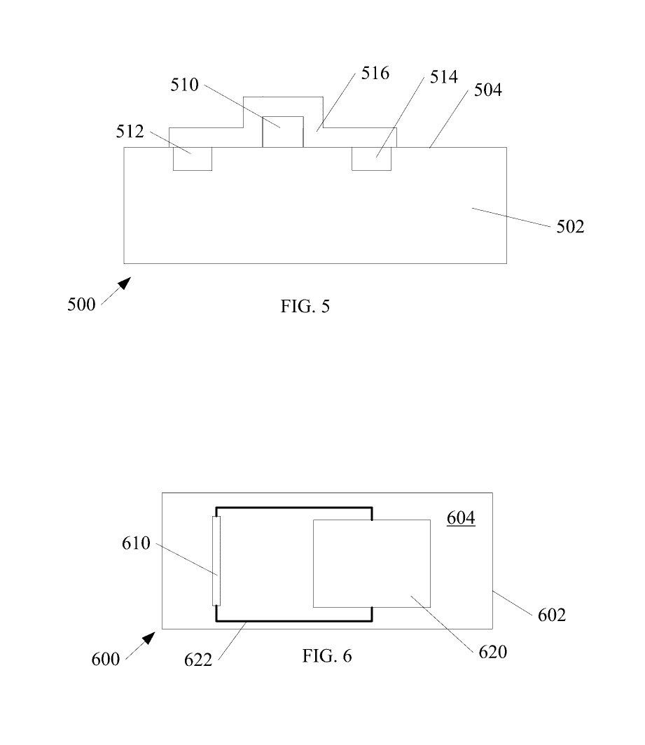

FIG. 5 shows one example of an electronic device 500 formed using iridium silicide structures such as nanowires formed on Si(110) surfaces as described above. An iridium silicide structure 510 such as a nanowire is formed on a Si(110) surface 504 of a silicon substrate 502. In the example shown, the electronic device 500 is a FinFET, that uses the iridium silicide structure 510 as a channel. The electronic device 500 example further includes electrical contacts 512, 514, coupled to a gate 516, which covers more than one side of the iridium silicide structure 510. In the example shown, the gate 516 covers three sides of the iridium silicide structure 510, which increases surface area, and improves function of the FinFET.

FIG. 6 shows another example of an electronic device 600 formed using iridium silicide structures such as nanowires formed on Si(110) surfaces as described above. An iridium silicide structure 610 such as a nanowire is formed on a Si(110) surface 604 of a silicon substrate 602. In the example shown, the electronic device 600 is an IR detector that uses the iridium silicide structure 610 as the detector element. Processing circuitry 620 is shown coupled to the iridium silicide structure 610 using circuitry 622. In one example, the processing circuitry 602 is used to identify changes in at least one electronic property of the iridium silicide structure 610 when it is exposed to IR wavelength radiation.

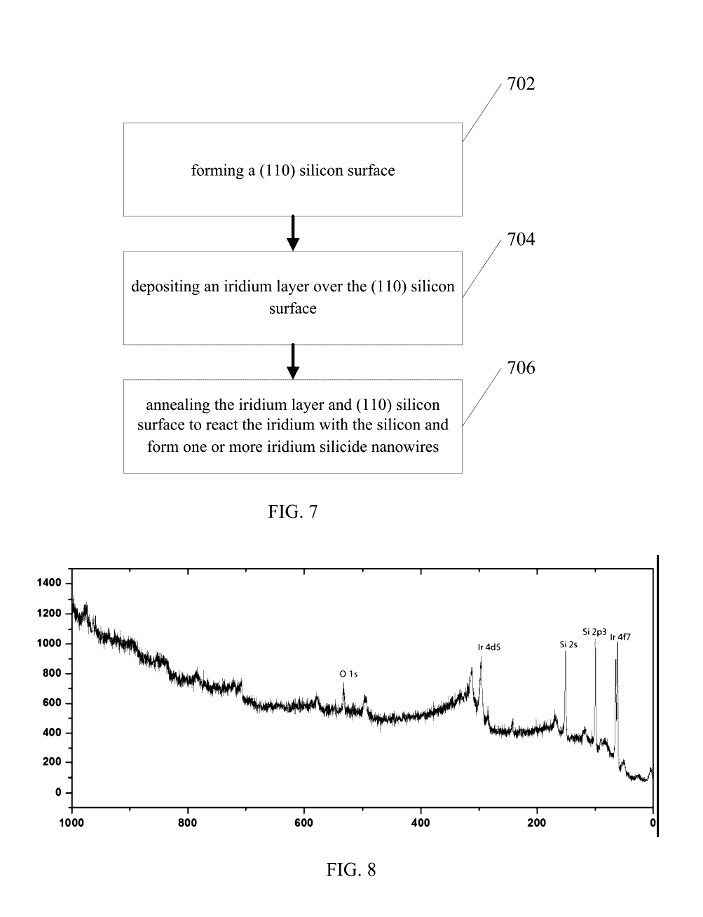

FIG. 7 shows an example method of forming an iridium silicide structures such as a nanowires on a Si(110) surface. In operation 702, a (110) silicon surface is formed. In selected examples the surface is processed to provide the necessary surface microstructure. One example includes annealing a cut Si(110) surface. Operation 704 shows depositing an iridium layer over the Si(110) surface. One example includes resistive heating of an iridium wire in a vacuum in proximity to the Si(110) surface. In operation 706, the iridium layer and (110) silicon surface are annealed to react the iridium with the silicon and form one or more iridium silicide nanowires.

FIG. 8 shows a plot of an x-ray photoelectron spectroscopy scan of an iridium silicide structure according to examples described above. The x-axis is binding energy, as measured in eV. The y-axis is detected counts. The plot was recorded at a photon energy of 1486.6 eV. The spectra shows various iridium and silicon peaks, proving that the nanowires are made out of iridium and silicon.

To better illustrate the method and apparatuses disclosed herein, a non-limiting list of examples is provided here:

Example 1 includes an electronic device, including an iridium silicide nanostructure formed on a (110) silicon surface plane, and at least one electrical contact coupled to the iridium silicide nanostructure.

Example 2 includes the electronic device of example 1, wherein the iridium silicide nanostructure includes a nanowire.

Example 3 includes the electronic device of any one of examples 1-2, wherein the iridium silicide nanowire is approximately 100 nanometers long.

Example 4 includes the electronic device of any one of examples 1-3, wherein the iridium silicide nanowire is approximately 15 nanometers wide.

Example 5 includes the electronic device of any one of examples 1-4, wherein the iridium silicide nanowire is approximately 2 nanometers high.

Example 6 includes the electronic device of any one of examples 1-5, wherein the (110) silicon surface plane includes bulk silicon.

Example 7 includes the electronic device of any one of examples 1-6, wherein the (110) silicon surface plane includes a silicon layer grown on a substrate.

Example 8 includes the electronic device of any one of examples 1-7, wherein the electronic device includes an infrared wavelength light detector.

Example 9 includes the electronic device of any one of examples 1-8, further including a transistor gate structure formed over the iridium silicide nanostructure.

Example 10 includes a method including forming a (110) silicon surface, depositing an iridium layer over the (110) silicon surface, and annealing the iridium layer and (110) silicon surface to react the iridium with the silicon and form one or more iridium silicide nanowires.

Example 11 includes the method of example 10, wherein forming the (110) silicon surface includes annealing a (110) silicon surface at a temperature lower than approximately 800° C.

Example 12 includes the method of example 11, wherein annealing the (110) silicon surface at a temperature lower than approximately 800° C. includes annealing the (110) silicon surface at a temperature between approximately 600° C. and 800° C.

Example 13 includes the method of example 10, wherein forming the (110) silicon surface includes annealing a (110) silicon surface at a temperature of approximately 600° C.

Example 14 includes the method of any one of examples 10-13, wherein annealing the iridium layer and (110) silicon surface includes annealing at approximately 800° C. for approximately two minutes.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1. An electronic device, comprising:
an iridium silicide nanostructure formed on a (110) silicon surface plane; and
at least one electrical contact coupled to the iridium silicide nanostructure.

2. The electronic device of claim 1, wherein the iridium silicide nanostructure includes a nanowire.

3. The electronic device of claim 1, wherein the iridium silicide nanowire is approximately 100 nanometers long.

4. The electronic device of claim 1, wherein the iridium silicide nanowire is approximately 15 nanometers wide.

5. The electronic device of claim 1, wherein the iridium silicide nanowire is approximately 2 nanometers high.

6. The electronic device of claim 1, wherein the (110) silicon surface plane includes bulk silicon.

7. The electronic device of claim 1, wherein the (110) silicon surface plane includes a silicon layer grown on a substrate.

8. The electronic device of claim 1, wherein the electronic device includes an infrared wavelength light detector.

9. The electronic device of claim 1, further including a transistor gate structure formed over the iridium silicide nanostructure.

10. A method, comprising:
forming a (110) silicon surface;
depositing an iridium layer over the (110) silicon surface; and
annealing the iridium layer and (110) silicon surface to react the iridium with the silicon and form one or more iridium silicide nanowires.

11. The method of claim 10, wherein forming the (110) silicon surface includes annealing a (110) silicon surface at a temperature lower than approximately 800° C.

12. The method of claim 11, wherein annealing the (110) silicon surface at a temperature lower than approximately 800° C. includes annealing the (110) silicon surface at a temperature between approximately 600° C. and 800° C.

13. The method of claim 10, wherein forming the (110) silicon surface includes annealing a (110) silicon surface at a temperature of approximately 600° C.

14. The method of claim 10, wherein annealing the iridium layer and (110) silicon surface includes annealing at approximately 800° C. for approximately two minutes.
